(19) United States
(12) Patent Application Publication
(10) Pub. No.: US 2003/0132747 A1
(43) Pub. Date: Jul. 17, 2003

(54) Thermal decay test method of magnetic hard disk

(76) Inventors: Sooyoul Hong, Sunnyvale, CA (US); Hyung Jai Lee, Cupertino, CA (US)

Correspondence Address: IRELL & MANELLA LLP, 840 NEWPORT CENTER DRIVE, SUITE 400, NEWPORT BEACH, CA, 92660, US

(21) Appl. No.: 10/051,987

(22) Filed: Jan. 16, 2002

(51) Int. Cl. G01R 33/12

(52) U.S. Cl. 324/212

(57) ABSTRACT

A test stand and method for testing a disk of a hard disk drive. The disk is placed onto a spindle motor of the test stand. The test stand also contains a head that is connected to a controller. The controller causes the head to write a reference signal and a test signal onto the disk. The amplitude of the reference signal is then reduced, typically with a DC erase current. The head reads back the test signal from areas of the disk that are heated by a heating element. The reference signal is also read back and used to normalize the test signal. Using a reference signal with a reduced amplitude has been found to produce less scattered data than methods of the prior art.

### BACKGROUND OF THE INVENTION

1. Field of the Invention

The subject matter disclosed generally relates to the field of hard disk drives.

2. Background Information

Hard disk drives contain a plurality of magnetic heads that are coupled to rotating disks. The heads write and read information by magnetizing and sensing the magnetic fields of the disk surfaces. There have been developed magnetic heads that have a write element for magnetizing the disks and a separate read element for sensing the magnetic fields of the disks. The read element is typically constructed from a magneto-resistive material. The magneto-resistive material has a resistance that varies with the magnetic fields of the disk. Heads with magneto-resistive read elements are commonly referred to as magneto-resistive (MR) heads.

Each head is attached to a flexure arm to create an subassembly commonly referred to as a head gimbal assembly (“HGA”). The HGA's are attached to an actuator arm that has a voice coil coupled to a magnet assembly. The voice coil and magnet assembly create a voice coil motor that can pivot the actuator arm and move the heads across the disks.

Information is typically stored within annular tracks that extend across each surface of a disk. The voice coil motor can move the heads to different track locations to access data stored onto the disk surfaces. Each track is typically divided into a plurality of adjacent sectors. Each sector may have one or more data fields. Each data field has a series of magnetic transitions that are decoded into binary data. The spacing between transitions define the bit density of the disk drive. It is generally desirable to provide a high bit density to increase the overall storage capacity of the drive.

The disks are typically tested before assembly into a hard disk drive unit. For example, the disks may be tested to determine the decay of a test signal as a function of time at room temperature or elevated temperature. This is sometimes referred to as a thermal decay test. The thermal decay test is typically conducted on a test stand that contains a spindle motor for rotating a disk. The test stand also contains a head for writing and reading signals from the disk, and a laser that can heat a localized area of the disk. The test stand initially writes a test signal on the disk, heats a portion of the disk and then reads back the test signal from the heated portion. The test signal data is then analyzed to determine whether the disk has an unacceptable thermal decay.

To remove system drift and head instabilities in the system, a reference track is typically written onto the disk, read back and then used to normalize the test signal. Even with the reference track it has been found that the thermal decay test may produced scattered data.

### BRIEF SUMMARY OF THE INVENTION

A test stand and method for testing a disk of a hard disk drive. The test method includes writing a reference signal onto a reference track of the disk and then reducing an amplitude of the reference signal. The method also includes writing a test signal, heating a portion of the disk, and reading back the test signal at the heated portion. The reference signal is also read back and used to normalize the test signal.

### BRIEF DESCRIPTION OF THE DRAWINGS

FIG. 1 is a top view of a hard disk drive;

FIG. 2 is an illustration of a test stand;

FIG. 3 is a graph showing thermal decay data using a method of the prior art and the present method.

### DETAILED DESCRIPTION

Disclosed is a test stand and method for testing a disk of a hard disk drive. The disk is placed onto a spindle motor of the test stand. The test stand also contains a head that is connected to a controller. The controller causes the head to write a reference signal and a test signal onto the disk. The amplitude of the reference signal is then reduced, typically with a DC erase current. The head reads back the test signal from areas of the disk that are heated by a heating element. The reference signal is also read back and used to normalize the test signal. Using a reference signal with a reduced amplitude has been found to produce less scattered data than methods of the prior art.

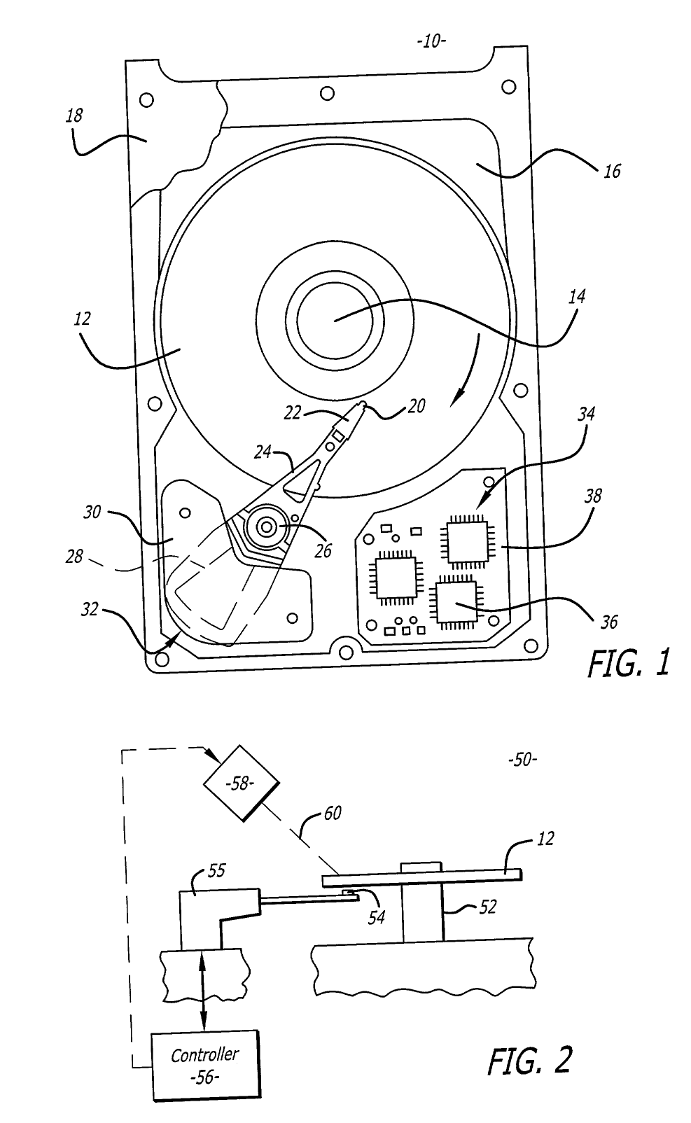

By way of background the various components and operation of a hard disk drive will be described. Referring to the drawings more particularly by reference numbers, FIG. 1 shows an embodiment of a hard disk drive 10. The disk drive 10 may include one or more magnetic disks 12 that are rotated by a spindle motor 14. The spindle motor 14 may be mounted to a base plate 16. The disk drive 10 may further have a cover 18 that encloses the disks 12.

The disk drive 10 may include a plurality of heads 20 located adjacent to the disks 12. The heads 20 may have separate write and read elements (not shown) that magnetize and sense the magnetic fields of the disks 12.

Each head 20 may be gimbal mounted to a flexure arm 22 as part of a head gimbal assembly (HGA). The flexure arms 22 are attached to an actuator arm 24 that is pivotally mounted to the base plate 16 by a bearing assembly 26. A voice coil 28 is attached to the actuator arm 24. The voice coil 28 is coupled to a magnet assembly 30 to create a voice coil motor (VCM) 32. Providing a current to the voice coil 28 will create a torque that swings the actuator arm 24 and moves the heads 20 across the disks 12.

Each head 20, has an air bearing surface (not shown) that cooperates with an air flow created by the rotating disks 12 to generate an air bearing. The air bearing separates the head 20 from the disk surface to minimize contact and wear. The formation of the air bearing and the general operation of the head 20 is a function of a force exerted by the flexure arm 22.

The hard disk drive 10 may include a printed circuit board assembly 36 that includes a plurality of integrated circuits 38 coupled to a printed circuit board 40. The printed circuit board 38 is coupled to the voice coil 28, heads 20 and spindle motor 14 by wires (not shown).

FIG. 2 shows a test stand 50 that can test the thermal decay of a disk 12. The test stand 50 includes a spindle motor 52 that can support and spin a disk 12. The test stand 50 also includes a head 54 located adjacent to the disk 12. The read/write head 54 is attached to an actuator 55 that can move the head 54 across the bottom surface of the disk 12.

The head 54 is connected to a controller 56. The controller 56 may contain a microprocessor, memory, drivers and other electrical circuits required to write and read signals onto the disk 12 through the head 54.

The test stand 50 may include a heating element 58 that can heat localized areas of the disk 12. The heating element 58 may be connected to the controller 56 to activate the element 58 at predetermined time intervals during a test routine of the disk 12. By way of example, the heating element 58 may be a laser that directs a laser beam 60 onto a spot of the disk 12.

The disk 12 can be tested for thermal decay by initially writing a reference signal onto a reference track of the disk 12. By way of example, the reference track may be located in an outer portion of the disk 12. A test signal is then written onto a different portion of the disk 12. The signals are written by the controller 56 and head 54.

The amplitude of the reference signal is then reduced. By way of example, the reference signal amplitude can be reduced with a DC erasing current from the head 54. The reference signal amplitude is preferably reduced 60-80% of the peak value. Although the method is described as first writing the reference signal, then the test signal and finally reducing the reference signal, it is to be understood that the order is not important. For example, the test signal can be written before the reference signal, or after reducing the reference signal amplitude.

After the signals are written, the heating element 58 is activated to heat a localized area of the disk 12. The head 54 then reads the test signal from the area of the disk 12 that has been heated. By way of example, the head 54 may be located adjacent to a first surface of the disk 12 while the laser beam 60 is directed onto a second opposite surface of the disk 12.

After reading the test signal the head 54 reads the reference signal from the disk 12. The reference signal is used to normalize the data of the test signal read from the heated portions of the disk 12.

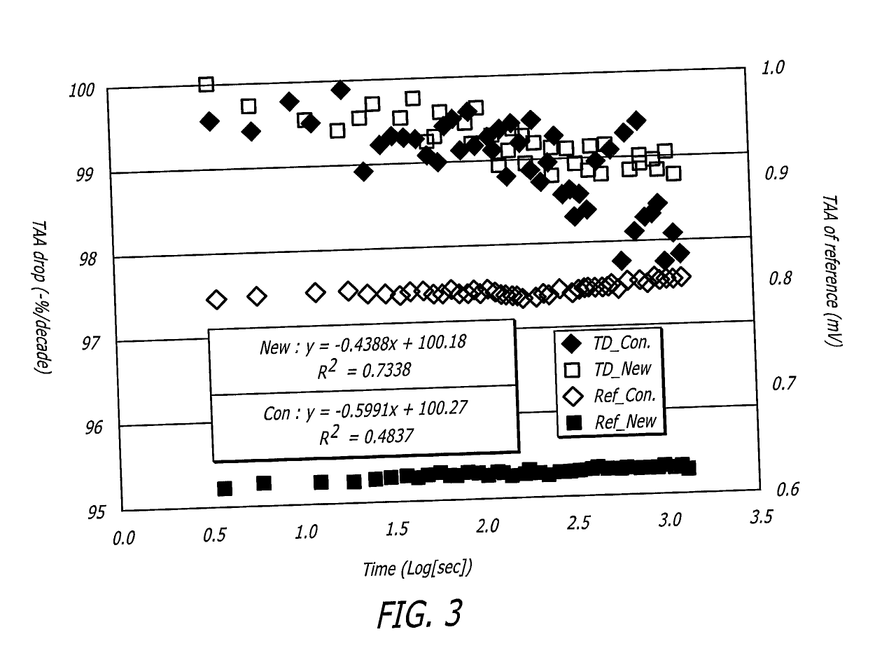

FIG. 3 shows thermal decay data using a conventional method of the prior art and the present method using a reduced amplitude reference signal. As shown by the graph, the conventional data tends to be scattered and tapers off with time. Test data normalized with a reduced amplitude reference signal tends to be less scattered and has less of a taper with time. Data that is less scattered allows the test stand to more accurately determine whether the disk 12 has an unacceptable thermal decay rate.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. A test stand for testing a thermal decay of a disk of a hard disk drive, comprising:
a spindle motor that can spin the disk;
a head coupled to the disk;
a heating element that can heat the disk;
a controller connected to said head, said controller operates in accordance with a procedure that writes a reference signal onto a reference track of the disk and then reduces an amplitude of the reference signal, writes a test signal onto the disk, reads the test signal when the disk is heated by the heating element, reads the reference signal, and normalizes the test signal with the reference signal.

2. The test stand of claim 1, wherein the amplitude of the reference signal is reduced with a DC erasing current from said head.

3. The test stand of claim 1, wherein the amplitude of the reference signal is reduced between 60 to 80% of a peak value.

4. The test stand of claim 1, wherein said heating element is a laser that directs a laser beam onto a portion of the disk.

5. The test stand of claim 4, wherein said head is on a first surface of the disk and the laser beam is directed onto an opposite second surface of the disk.

6. A method for testing a thermal decay of a disk of a hard disk drive, comprising:
writing a reference signal onto a reference track of the disk;
writing a test signal onto the disk;
reducing an amplitude of the reference signal;
heating a portion of the disk;
reading the test signal from the heated portion of the disk;
reading the reference signal; and
normalizing the test signal with the reference signal.

7. The method of claim 6, wherein the amplitude of the test signal is reduced with a DC erase signal.

8. The method of claim 7, wherein the amplitude of the test signal is reduced 60 to 80% of a peak value.

9. The method of claim 6, wherein the disk is heated with a laser beam.

10. The method of claim 9, wherein the test signal is read with a head located adjacent to a first surface of the disk, and the laser beam is directed onto an opposite second surface of the disk.
